(19) United States
(12) Patent Application Publication
(10) Pub. No.: US 2026/0206641 A1
(43) Pub. Date: Jul. 16, 2026

(54) SYSTEMS AND METHODS FOR STACKED MEMORY PACKAGING

(71) Applicant: Sandisk Technologies, Inc., Milpitas, CA (US)

(72) Inventors: Cong Zhang, Shanghai (CN); Pradeep Kumar Rai, Bengaluru (IN); Yiqin Huang, Shanghai (CN); Xuyi Yang, Shanghai (CN)

(73) Assignee: Sandisk Technologies, Inc., Milpitas, CA (US)

(21) Appl. No.: 19/015,724

(22) Filed: Jan. 10, 2025

(51) Int. Cl. H01L 25/16; H01L 21/56; H01L 23/00; H01L 23/18; H01L 23/31; H01L 23/48; H01L 23/538; H01L 23/64; H10B 80/00; H10D 80/30

(52) U.S. Cl. CPC H10W 90/00; H10B 80/00; H10D 80/30; H10W 44/601; H10W 70/611; H10W 70/65; H10W 74/016; H10W 74/121; H10W 20/20; H10W 72/879; H10W 72/9445; H10W 76/42; H10W 80/312; H10W 80/327; H10W 90/24; H10W 90/724; H10W 90/752; H10W 90/754; H10W 90/792

(57) ABSTRACT

A memory device includes a plurality of memory dies arranged in a stack with electrical connectors configured to transfer signals to and from the memory dies. The memory dies are encapsulated within a first mold compound so that ends of the electrical connectors extend to an active surface of the first mold compound. The first mold compound has a depression in the active surface. A memory controller die is located in the depression. The memory controller die is encapsulated in a second mold compound in the depression and has an active surface that is coplanar with the active surface of the first mold compound.

### BACKGROUND

The present disclosure relates to non-volatile memory.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in a memory system typically contains many memory cells and various control lines. The memory structure may be three-dimensional (3D) and may include vertical NAND strings. Other memory structures may also be used.

A memory system may have control circuits to perform various operations (e.g., read, write and erase). Some or all control circuits may be located on a separate die (e.g., a memory structure may be located on a memory die and control circuits may be located on a control die that is bonded to the memory die). Memory dies (with or without control dies) may be arranged in a stack. In some cases, a memory system may include a memory controller die and/or other dies that is/are connected to a stack of memory dies. Electrically connecting dies in such a memory system in a reliable and cost-effective manner may be challenging.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 3A and 3B depict different embodiments of memory assemblies.

FIG. 4 shows a die stack with electrical conductors (bond wires).

FIG. 5 shows a die stack including a stepped region with electrical conductors.

FIGS. 6A-C illustrate an example of an encapsulated die stack.

FIGS. 7A-I show an example of an encapsulated die stack with additional dies located in a depression.

FIGS. 8A-C show an example of a depression formed for additional dies.

FIGS. 9A-B show an example of an encapsulated die stack with bond wires on one side.

FIGS. 10A-B show an example of an encapsulated die stack with two die stacks, each having bond wires on one side.

FIG. 11 shows an example of a method that includes locating one or more additional dies in a depression and filling the depression with a mold compound.

### DETAILED DESCRIPTION

A die stack may be formed of multiple dies, which may include memory dies, and may be encapsulated (e.g., using mold compound). Bond wires may extend (e.g., vertically) from a die stack to enable connection between the die stack and additional dies (e.g., memory controller die, volatile memory die and/or integrated passive device (IPD) die). Ends of bond wires may be exposed along an active surface of the encapsulant (e.g., mold compound). In an example, a depression (e.g., a trench) is formed in the encapsulant over the die stack and the one or more additional dies are located in the depression so that active surfaces of the one or more additional dies are coplanar with the active surface of the encapsulant along which ends of bond wires are exposed. For example, additional dies may be mounted face-down on a planar surface of a carrier (e.g., with active surfaces lying in contact with the planar surface of the carrier). Another encapsulant (second mold compound) then fills the depression around the one or more additional dies in the depression so that they are maintained in a co-planar arrangement. The carrier may be removed to expose active surfaces of the encapsulant and the additional dies (which are coplanar). A redistribution layer (RDL) may then be attached to the exposed ends of bond wires and to bond pads on the active surfaces of the additional dies to form appropriate electrical connections between the die stack and the additional dies.

Aspects of the present technology are directed to technical problems associated with connecting and packaging die stacks (e.g., stacks containing multiple memory dies) and additional dies (e.g., one or more memory controller die, volatile memory die and/or integrated passive device die). Aspects of the present technology provide technical solutions including forming a depression or trench in an encapsulant of an encapsulated die stack and locating additional dies (e.g., memory controller) in the depression so that they have active surfaces that are coplanar with ends of bond wires and filling the depression with encapsulant to maintain the coplanar arrangement. Subsequently, a redistribution layer (RDL) may connect the additional dies and the die stack.

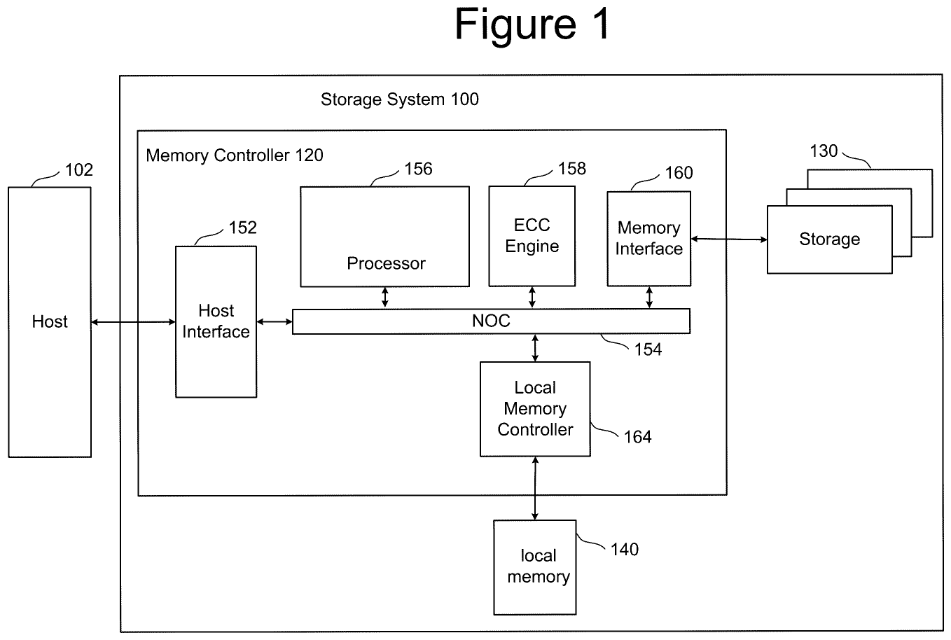

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus.

Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface 160 provides a Toggle Mode interface. Other interfaces can also be used. In some example implementations, memory interface 160 (or another portion of memory controller 120) implements a scheduler and buffer for transmitting data to and receiving data from one or more memory die.

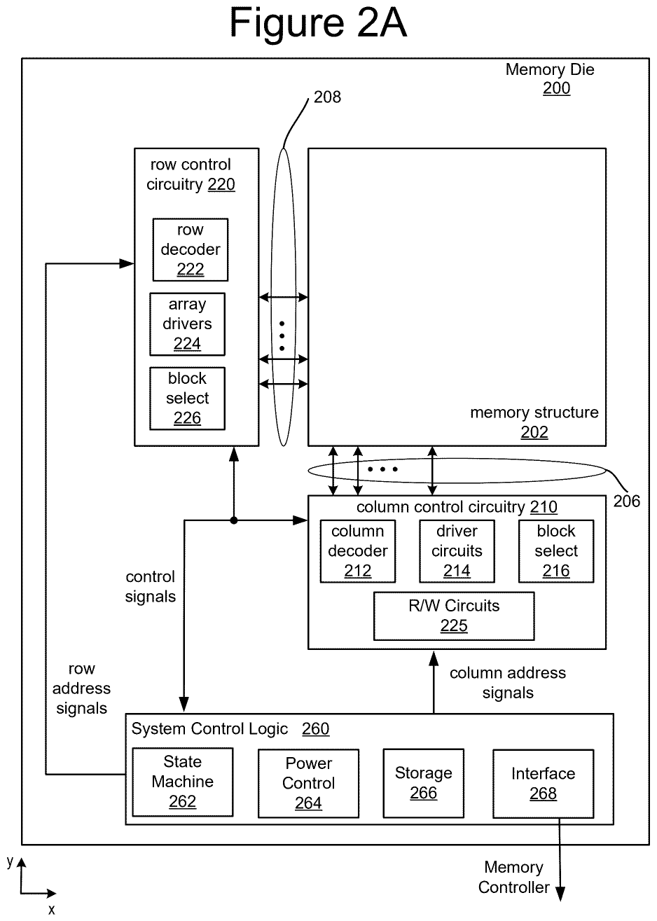

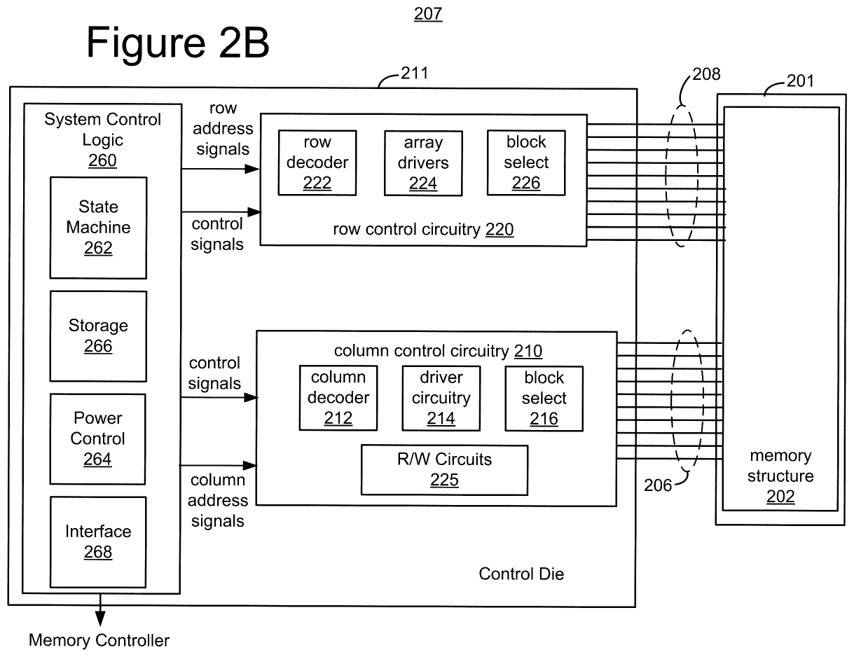

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic 260, and typically may include such circuits as row decoders 222, array drivers 224, and block select circuit 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only a single block is shown for memory structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuit 216, as well as read/write circuitry, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate memory controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuits 214, and block select circuit 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select circuit 226 are coupled to memory structure 202 through electrical paths 208. Each of electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of memory controller 120, state machine 262, power control module 264, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, storage 130, memory die 200, integrated memory assembly 207, and/or control die 204.

In some embodiments, there is more than one control die 204 and more than one memory structure die 200 in an integrated memory assembly 207. In some embodiments, the integrated memory assembly 207 includes a stack of multiple control dies 204 and multiple memory structure dies 200.

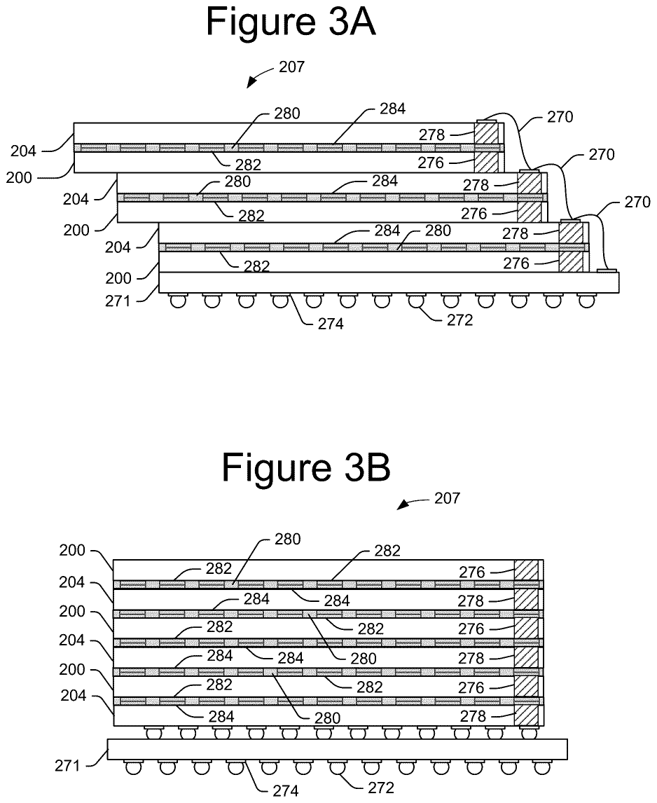

FIG. 3A depicts a side view of an embodiment of an integrated memory assembly 207 stacked on a substrate 271 (e.g., a stack comprising control die 204 and memory structure die). The integrated memory assembly 207 has three control dies 204 and three memory structure dies 200. In some embodiments, there are more than three memory structure dies 200 and more than three control dies 204. In FIG. 3A there are an equal number of memory structure dies 200 and control dies 204; however, in one embodiment, there are more memory structure dies 200 than control dies 204. For example, one control die 204 could control multiple memory structure dies 200.

Each control die 204 is affixed (e.g., bonded) to at least one of the memory structure die 200. Some of the bond pads 282/284 are depicted. There may be many more bond pads. A space between two die 200, 204 that are bonded together is filled with a solid layer 280, which may be formed from epoxy or other resin or polymer. This solid layer 280 protects the electrical connections between the die 200, 204, and further secures the die together. Various materials may be used as solid layer 280.

The integrated memory assembly 207 may for example be stacked with a stepped offset, leaving the bond pads at each level uncovered and accessible from above. Bond wires 270 connected to the bond pads connect the control die 204 to the substrate 271. A number of such bond wires may be formed across the width of each control die 204 (i.e., into the page of FIG. 3A).

A memory die through silicon via (TSV) 276 may be used to route signals through a memory structure die 200. A control die through silicon via (TSV) 278 may be used to route signals through a control die 204. The TSVs 276, 278 may be formed before, during or after formation of the integrated circuits in dies 200, 204. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control dies 204 and three memory structure dies 200. In some embodiments, there are many more than three memory structure dies 200 and many more than three control dies 204. In this example, each control die 204 is bonded to at least one memory structure die 200. Optionally, a control die 204 may be bonded to two or more memory structure dies 200.

Some of the bond pads 282, 284 are depicted. There may be many more bond pads. A space between two dies 200, 204 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory structure die 200. A control die through silicon via (TSV) 278 may be used to route signals through a control die 204.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 204 and the memory structure die 200 may be bonded together. Bond pads on each die 200, 204 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor die together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 200, 204. Where no such film is initially provided, a space between the die may be under filled with an epoxy or other resin or polymer. The under-fill material may be applied as a liquid which then hardens into a solid layer. This under-fill step protects the electrical connections between the dies 200, 204, and further secures the die together. Various materials may be used as under-fill material.

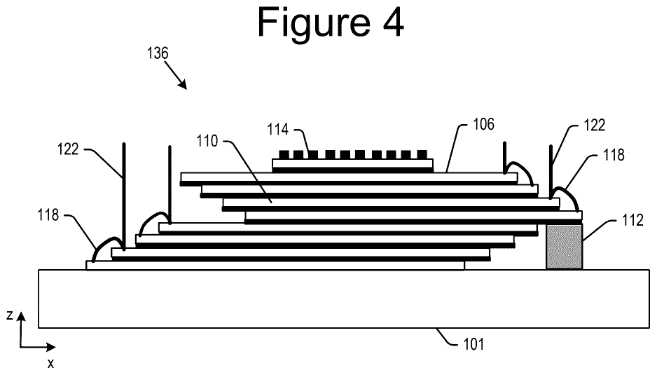

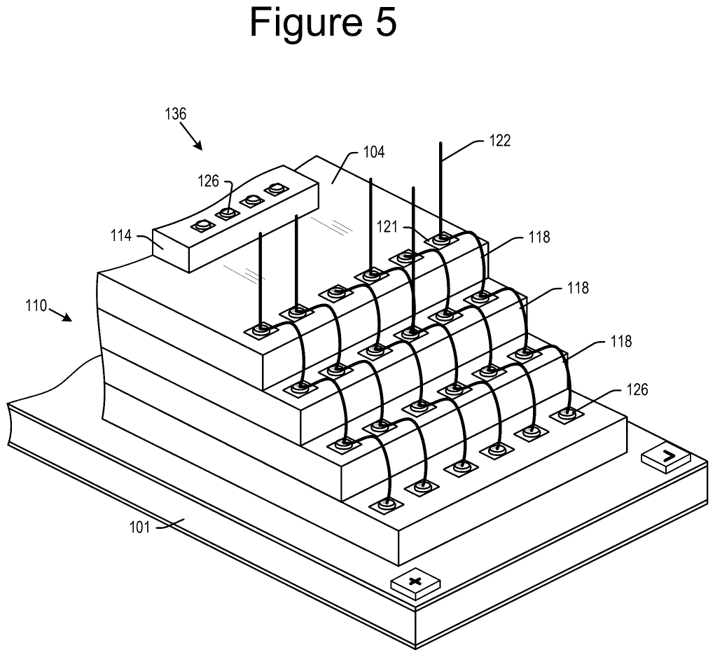

FIGS. 4-5 show another example of stacked semiconductor dies 106 in a semiconductor package 136. The semiconductor dies 106 may for example be memory dies such a NAND flash memory die, but other types of die 106 may be used. The memory dies may be in the form of integrated memory assemblies (also referred to as a CMOS bonded array or “CbA” module” including a memory die bonded to control die (e.g., logic or CMOS die). The semiconductor dies 106 may be stacked atop each other in an offset (FIG. 3A) or double offset (FIG. 4) stepped configuration to form a die stack 110, which is shown extending in the z-direction (e.g., dies are stacked along the z-direction). The double offset configuration of FIG. 4 may comprise a spacer block 112 to support the upper dies 106 during wire bonding and encapsulation. The spacer block may be omitted in further embodiments.

In the example shown, the semiconductor package 136 includes eight semiconductor die 106. However, the die stack 110 may include more or less than eight semiconductor die in further embodiments, including for example 2, 4, 16 and 32 semiconductor die. The die 106 may be affixed to each other in the die stack 110 using a DAF (die attach film). As one example, the DAF may be 8988UV epoxy from Henkel Corp of California, USA.

In some examples, a memory controller die 114 may be mounted on top of the die stack 110. The memory controller die 114 may be an ASIC for controlling flow of data and signals to/from the die stack 110 (e.g., may include some or all of the circuits of memory controller 120 such as host interface circuits 152 and memory interface circuits 160).

Once the die stack 110 and memory controller die 114 are mounted on the carrier 101, the respective dies 106 and 114 may be electrically connected to each other using bond wires 118. FIGS. 4 and 5 show simplified edge and perspective views with a few bond wires shown for illustration purposes. There may be many more bond wires 118 than shown. Each semiconductor die 106 may include a row of die bond pads 121 along one or both edges of the dies 106. It is understood that each die 106 may include many more die bond pads 121 than is shown in FIG. 5. Each die bond pad 121 in the row of a semiconductor die may be electrically connected to the corresponding die bond pad 121 in the row of the next adjacent semiconductor die using a bond wire 118 formed as described below.

In order to connect bond wires 118, in embodiments, a stud bump 126 may initially be deposited on each of the die bond pads 121. After the stud bumps 126 are deposited on the bond pads 121, stitch wire bonds 118 may be formed on the stud bumps 126 on a die 106 (for example on the bottom die 106) up to the corresponding stud bumps 126 on the next higher die (for example the second die 106 from the bottom). This process may be repeated up the die stack 110 until bond wires 118 are formed between all corresponding die bond pads 121 in a column of die bond pads in die stack 110.

In order to form the fanout package of the present technology, electrical connections outside of the package may be made upward from the die stack (e.g., along the z-direction). As such, the die stack 110 may further include vertical bond wires 122 used for external electrical connections (e.g., forming electrical connectors configured to transfer signals to and from the plurality of memory dies in the stack). The vertical bond wires 122 shown in FIGS. 4 and 5 are by way of example only, and there may be more or less vertical bond wires 122 in further embodiments.

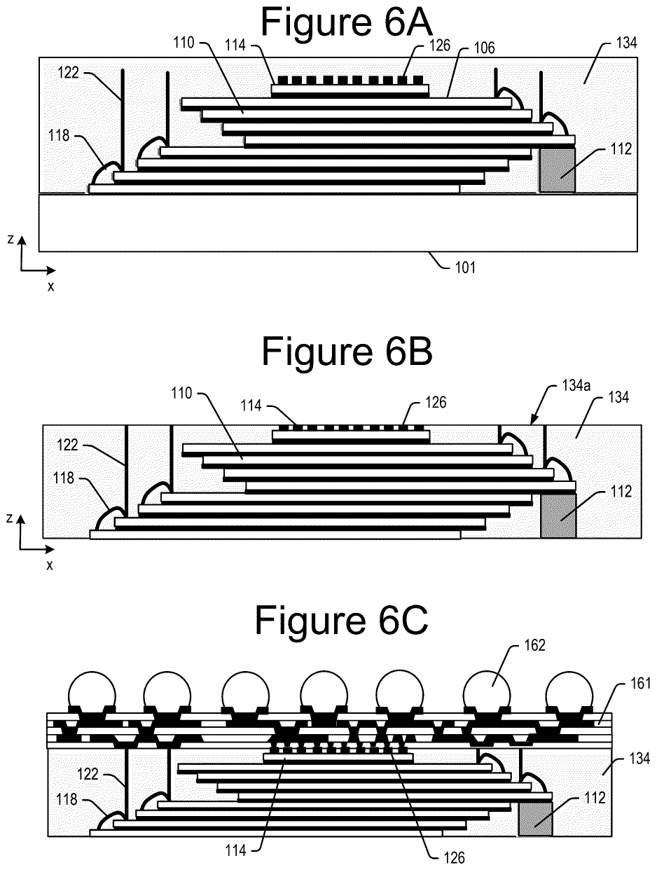

After the electrical connections are formed, the die stack 110 may be encapsulated in a mold compound 134 (encapsulant) as shown in FIG. 6A. The mold compound may be applied onto the surface of the carrier 101, surrounding and encapsulating die stack 110 and memory controller die 114, as well as the bond wires 118 and 122. Mold compound 134 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other mold compounds from other manufacturers are contemplated. The mold compound may be applied according to various known processes, including by FFT (flow free thin) molding, transfer molding or injection molding techniques.

At this stage, the respective fanout packages may be defined within the mold compound 134. As shown in the figures, the overall footprint (length and width) of a semiconductor die 106, and also the die stack 110, may be slightly smaller than a footprint of the mold compound 134 in fanout package. As explained below, an RDL pad may be affixed to the mold compound, which may have the same footprint as the surface of the mold compound to which it is attached. Multiple semiconductor packages 136 may be formed on the first temporary carrier 101. The mold compound may be applied across the entire surface of the rigid carrier 101, forming a block of mold compound encapsulating all of the packages 136 on the carrier 101.

A grinding process may be performed at a top surface of the mold compound 134 as illustrated by FIG. 6B (showing the results of grinding). The grinding process exposes the vertical bond wires 122, and also exposes the stud bumps 126 on top of memory controller die 114. The surface of the mold compound 134 for each fanout package 136 including the exposed electrical connections is referred to herein as the active surface 134a of the fanout packages 136 and mold compound 134.

An RDL 161 and solder balls 162 may be attached to the active surface 134a as shown in FIG. 6C. RDL 161 includes a first surface having an adhesive to affix the RDL 161 directly to active surface 134a of mold compound 134. The first surface of the RDL 161 includes a number of contact pads having positions and a configuration to mate with the exposed vertical bond wires 122 and the stud bumps 126 exposed at the active surface 134a.

The RDL 161 includes an electrical conductance pattern formed of a number of electrical traces and vias (electrical conductors) which electrically couple (effectively, redistributing) the vertical bond wires 122 and stud bumps 126 with select ones of the solder balls 162. It is understood that the pattern of solder balls 162, electrical traces and vias are shown by way of example only, and the RDL 161 may include other patterns of solder balls 162, traces and vias in further embodiments.

In another example (different to that shown in FIG. 6C), one or more dies, such as a controller die and/or other dies, may be combined with a stack of memory dies (e.g., CbA dies) in a manner that may provide some advantages over the arrangement of FIG. 6C. For example, aspects of the present technology include forming a stack of dies (e.g., memory dies or CbA dies such as die stack 110) that may not include a memory controller die, adding wires (e.g., bond wires 118 and 122 of FIG. 4) and then adding mold compound. Subsequently, one or more depressions such as a trench, indentation, opening or other depression may be formed in an active surface of the mold compound (e.g., at a location above the stack) to accommodate one or more additional dies (e.g., a memory controller die and/or other die(s)). The additional dies may be mounted on a carrier that is aligned with the depression (trench, indentation, opening or depression) with their active side(s) along a planar surface of the carrier, which is placed in contact with the active surface of the mold compound so that the active surfaces of the additional dies are coplanar with the active surface of the mold compound. A second mold compound may be used to encapsulate the additional die(s) (e.g., to fill the trench in the first mold compound) and physically attach the additional die(s) with the package that includes the die stack (e.g., to maintain the coplanar arrangement). An RDL may then be attached so that it connects bond pads on the active surface(s) of the additional dies and ends of vertical bond wires, which are located along a common plane. In this arrangement, stud bumps 126 may be unnecessary and bond pads on an additional die (e.g., memory controller die 114) may be bonded to corresponding pads of an RDL without stud bumps 126, which may improve reliability and reduce cost.

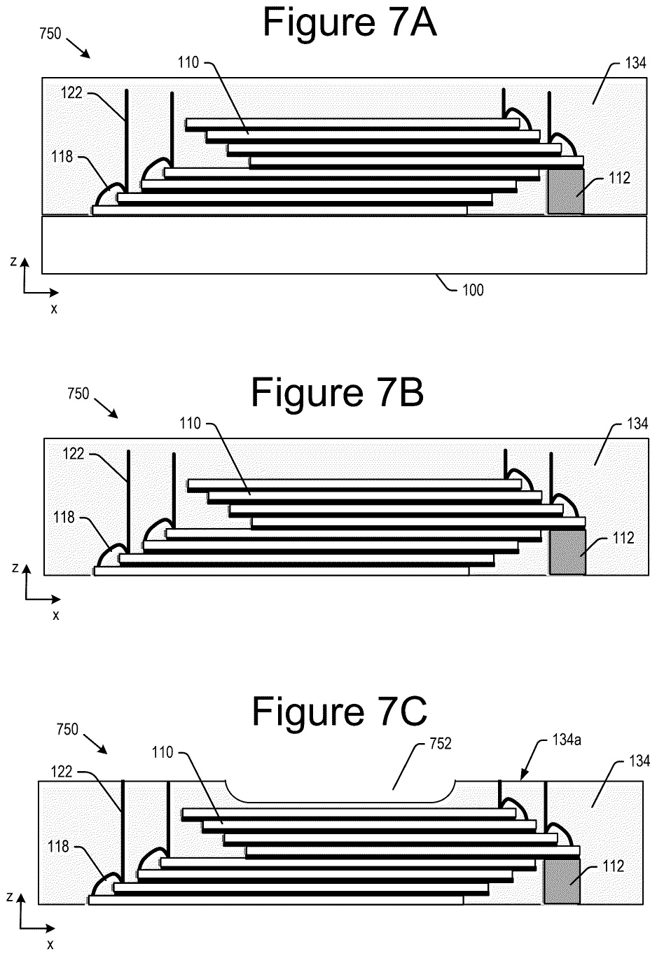

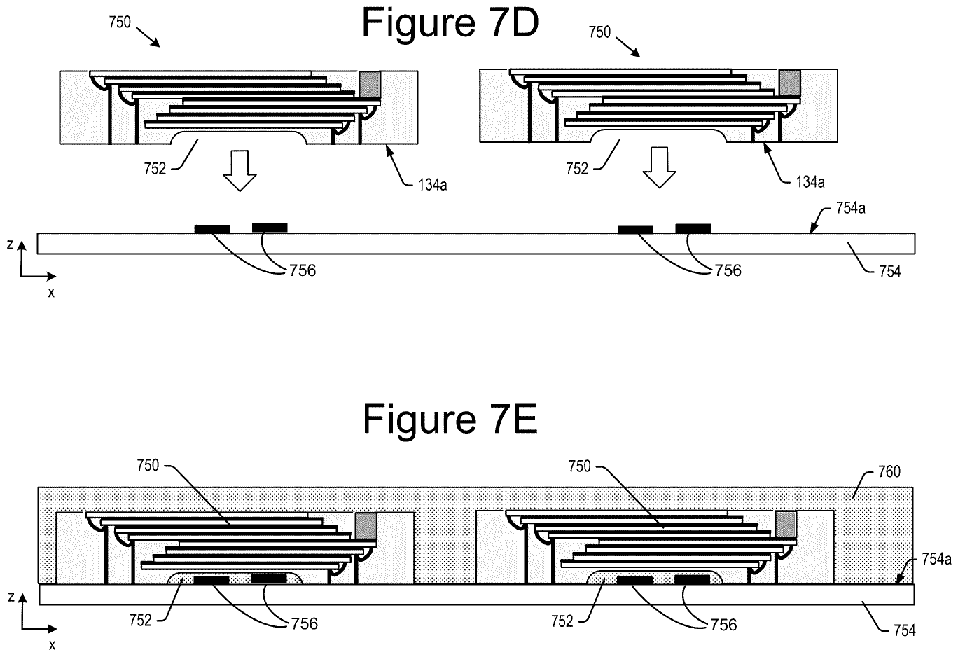

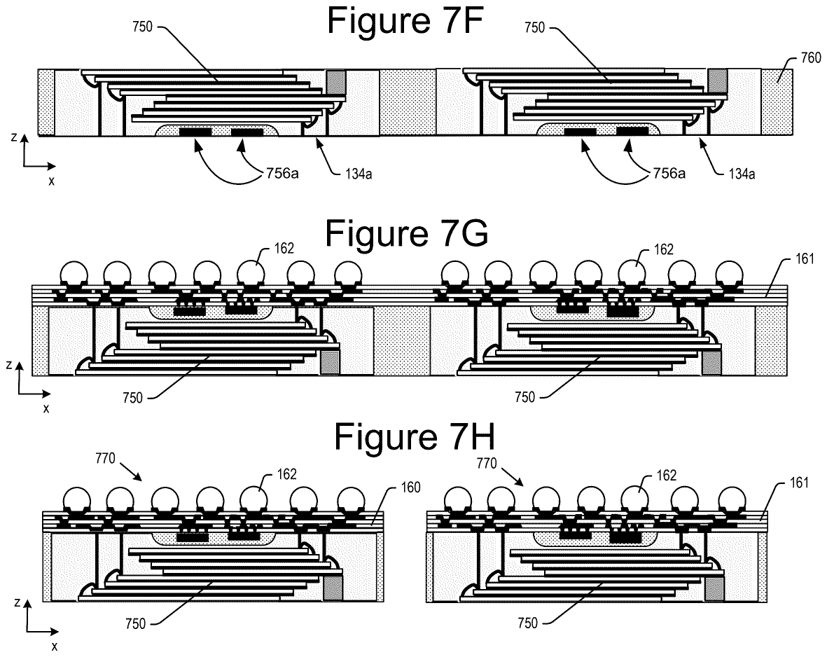

FIGS. 7A-I show an example of a method of packaging a stack of dies that uses aspects of the present technology and provides various advantages over alternative methods (e.g., over the method of FIGS. 6A-C). FIG. 7A shows encapsulated die stack 750, which includes die stack 110 (e.g., memory dies, which may be bonded to control dies, or otherwise) on carrier 101 with bond wires 118 and 122 covered by a first mold compound 134. In contrast to FIG. 6A, memory controller die 114 is not placed on die stack 110 prior to encapsulation by first mold compound 134 in this example.

FIG. 7B shows encapsulated die stack 750 of FIG. 7A after removal of carrier 101. In some cases, a portion of carrier 101 and/or an intermediate layer between carrier 101 and die stack 110 may remain at this stage.

FIG. 7C shows encapsulated die stack 750 after removal of first mold compound 134 to expose ends of bond wires 122 along active surface 134a of first mold compound 134 (e.g., by grinding, polishing or otherwise removing material to achieve a planar surface). Dual side grinding or other such technique may be used to remove any remaining portion of carrier 101 and/or intermediate layer from the opposite side of encapsulated die stack 750. In addition, first mold compound 134 is removed to form a depression 752 in active surface 134a (e.g., depression 752 is formed by removing a portion of first mold compound 134 after exposure of active surface 134a so that depression 752 extends into first mold compound 134). Depression 752 may be formed in any suitable manner (e.g., mechanical grinding, drilling, scraping or other mechanical removal; laser ablation; chemical or chemical-mechanical removal or other method or combination of methods). Depression 752 may have any suitable shape (e.g., circular, square, rectangular or other). In an example, depression 752 is formed by a trench that may extend across multiple encapsulated die stacks. Depression 752 is shown located over die stack 110 (e.g., at or near the middle of encapsulated die stack 750). In other examples, depression 752 may be located at or near an edge of an encapsulated die stack. In some examples, more than one depression may be provided.

FIG. 7D shows an example of how encapsulated die stack 750 of FIG. 7C may be combined with additional dies. Multiple encapsulated die stacks 750 may be formed as illustrated in FIG. 7C and two are shown in FIG. 7D. Encapsulated die stacks 750 are inverted with respect to FIG. 7C (e.g., active surface 134a is the lower surface and depression 752 faces down) with a second carrier 754 (wafer/panel carrier) located under encapsulated die stacks 750. Additional dies 756 are mounted on surface 754a of second carrier 754 with active surfaces facing down (e.g., active surfaces lying along and in contact with surface 754a). Active surfaces of additional dies 756 may have bond pads for connecting additional dies 756 with dies of die stack 110. Additional dies 756 may be spaced apart in a predetermined pattern. Encapsulated die stacks 750 may be aligned with the additional dies 756 and placed so that additional dies 756 are located in depressions 752 and active surfaces 134a of encapsulated die stacks 750 lie in contact with surface 754a. Surface 754a may be planar or substantially planar so that placing active surfaces 134a in contact with surface 754a places active surface 134a of first mold compound 134 (encapsulant) in a coplanar arrangement with the active surfaces of additional dies 756.

FIG. 7E shows the second carrier 754 with encapsulated die stacks 750 after placing encapsulated die stacks 750 with active surfaces 134a in contact with surface 754a thereby aligning active surfaces of additional dies 756 and active surfaces 134a of first mold compound 134. FIG. 7E also shows second mold compound 760 (second encapsulant) which is applied to cover and fill spaces between encapsulated die stacks 750. Second mold compound 760 also fills depressions 752. For example, depressions 752 may be in the form of trenches that are open at one or more sides so that second mold compound 760 can flow into depressions 752 (e.g., perpendicularly to the plane of the cross-sectional view of FIG. 7E). By filling depression 752, second mold compound physically attaches additional dies 756 and encapsulated die stacks 750 so that the coplanar arrangement shown may be maintained (e.g., after removal of second carrier 754).

FIG. 7F shows encapsulated die stacks 750 after removal of second carrier 754 and removal of excess second mold compound 760 (e.g., by grinding, polishing or otherwise). Removal of second carrier 754 leaves active surfaces 756a of additional dies 756 exposed (e.g., exposing bond pads on active surfaces 756a). Also exposed are ends of bond wires 122 at active surfaces 134a of first mold compound 134, which are coplanar with active surfaces 756a.

FIG. 7G shows the encapsulated die stacks 750 after attachment of an RDL 161 and solder balls 162. In FIG. 7G, encapsulated die stacks 750 are inverted with respect to FIG. 7F so that active surfaces 756a and 134a are facing up (positive z-direction) for connection with RDL 161. For example, a lower surface of RDL 161 may be planar or substantially planar so that bond pads along the lower surface lie in contact with corresponding bond pads on active surfaces 756a of additional dies 756 and ends of bond wires 122 at active surfaces 134a to enable bonding without stud bumps or other such features. RDL 161 connects pads on the active surface 756a with ends of bond wires 122 at the active surface of the encapsulant. The combination of second carrier 754, second mold compound 760 (second encapsulant) and RDL 161 may be considered an example of means for aligning an active surface of a die with the active surface of an encapsulant in a coplanar arrangement, maintaining the coplanar arrangement and electrically connecting pads on the active surface of the die with ends of the electrical connectors at the active surface of the encapsulant.

FIG. 7H shows encapsulated die stacks 750 of FIG. 7G after package singulation to separate individual packages 770. Each individual package 770 includes a die stack connected to additional dies by an RDL 161 with solder balls 162 for connection with additional circuits (e.g., with a host and/or additional packages).

FIG. 7I shows a more detailed view of a portion of package 770 including an interface between RDL 161 and encapsulated die stack 750 that extends along a plane 772 (e.g., active surfaces 756a and 134a may extend along plane 772 where they may be bonded to RDL 161). Pairs of bond pads 774 connect additional die 756 with RDL 161 (e.g., bond pads on active surface 756a of additional die 756 are bonded with corresponding bond pads on the lower surface of RDL 161). Bonds 776 connect bond wires 122 with RDL 161. Circuits in additional die 756 may connect with components of dies in encapsulated die stack 750 through RDL 161. Circuits in additional die 756 may also connect with components outside package 770 through solder balls 162.

In an example, additional dies 756 include a memory controller die (e.g., a die that includes some or all of the components of memory controller 120) which is connected with memory cells in memory dies of encapsulated die stack 750 through RDL 161. For example, additional die 756 of FIG. 7I may be a memory controller die that connects with memory dies (in integrated memory assemblies or otherwise) through pairs of bond pads 774, RDL 161, bonds 776 and bond wires 122. For example, such connections may be used to convey supply voltages, clock signals, user data, address data and/or other electrical signals.

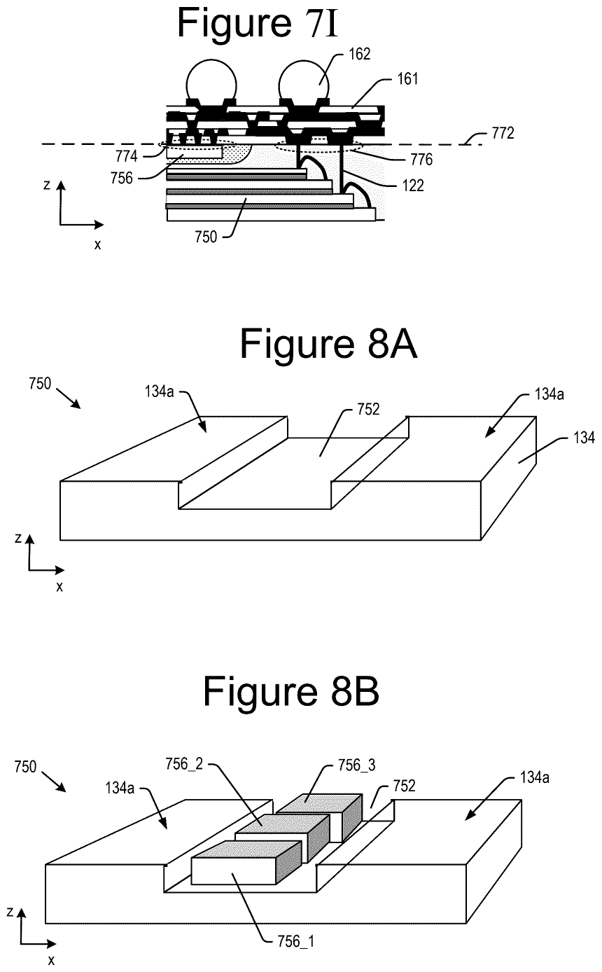

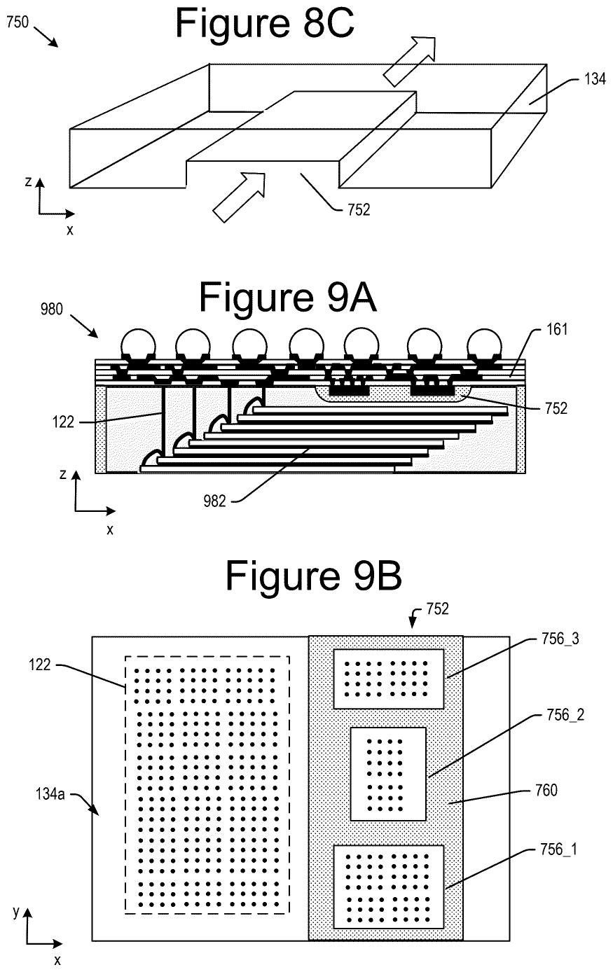

In some examples, depression 752 is formed as a trench that may extend across multiple encapsulated die stacks. FIG. 8A shows an example in which depression 752 is a trench that extends into first mold compound and extends from one edge of active surface 134a (front edge in FIG. 8A) to the opposite edge (far edge in FIG. 8A) so that it divides active surface 134a into two portions each of which may have exposed ends of bond wires. The dimensions of depression 752 (depth and lateral dimensions) may be sufficient to accommodate one or more additional dies 756 for connection with encapsulated die stack 750.

FIG. 8B shows an example in which three additional dies 756_1, 756_2 and 756_3 are provided, each of which may be connected to encapsulated die stack 750 and/or to each other and/or external circuits through a RDL (not shown in FIG. 8B). While a memory controller die is an example of an additional die that may be included in additional dies 756, the present technology is not limited to any particular additional die or dies. For example, additional die 756_1 may be a memory controller die with some or all of the circuits of memory controller 120 and/or other control circuits (e.g., formed as an Application Specific Integrated Circuit or ASIC). Additional die 765_2 may be a volatile or nonvolatile memory that is connected with memory controller die 756_1 (e.g., to function as local or high-speed memory). In one example, additional die 756_2 is a Dynamic Random Access Memory (DRAM) die, Static RAM (SRAM) or other volatile memory die. Additional die 756_3 may be an Integrated Passive Device (IPD) die that contains one or more passive device such as a capacitor. In some cases, capacitors of IPD die 756_3 may be used by charge pumps to generate voltages for memory operations that may be higher than a supplied voltage (e.g., a supply voltage provided by a host). In some examples, additional dies 756 may include multiple dies that perform different functions (e.g., instead of a just a single memory controller die) and these dies, which may be smaller than a memory controller die may be referred to as chiplets. In a chiplet design, the memory controller die is broken into separate modules, where the separate modules also may include an AI accelerator, a LDPC engine, an interface, etc. By breaking the single control die down into multiple subblocks (i.e., chiplets), then functions may be added or removed from memory devices based on a specific performance requirements or functions needed.

Forming depression 752 as a trench that extends from one side of an encapsulated die stack to the opposite side may have some advantages. For example, FIG. 8C shows an example of encapsulated die stack 750 during formation of second mold compound 760 where the flow of second mold compound 760 through depression 752 is illustrated by arrows. Enabling flow in this way may ensure that depression 752 is adequately filled around additional dies 756, without significant voids, gaps or bubbles, so that additional dies 756 are securely and uniformly maintained in a coplanar arrangement.

While the example of FIGS. 8A-C shows depression 752 extending across the middle of active surface 134a so that it is located directly above die stack 110 and has ends of bond wires exposed on active surface 134a on either side, other arrangements are possible and the present technology is not limited to any particular configuration of active surface(s) and depression(s). For example, for different die stack arrangements different arrangements of active surface(s) and depression(s) may be convenient.

FIG. 9A shows an example of an encapsulated die stack 980 that includes a die stack 982 that is stepped on only one side so that all bond wires 122 are on one side (left side in FIG. 9A) of die stack 982. In this example, depression 752 is located on the other (right) side of encapsulated die stack 980 (e.g., over a central area of the topmost die in die stack 982).

FIG. 9B shows a top-down view of encapsulated die stack 980. Additional dies 756_1, 756_2 and 756_3 are shown in depression 752 surrounded by second mold compound 760. Ends of bond wires 122 are exposed at active surface 134a on one side of depression 752 (on left side in FIG. 9B). Active surface 134a is coplanar with exposed (upper) surfaces of additional dies 756_1, 756_2 and 756_3 to facilitate bonding by an RDL with a planar surface. Connections of a corresponding RDL may be configured accordingly to have bond pads that align with ends of bond wires 122 of active surface 134a and with bond pads on additional dies 756_1, 756_2 and 756_3.

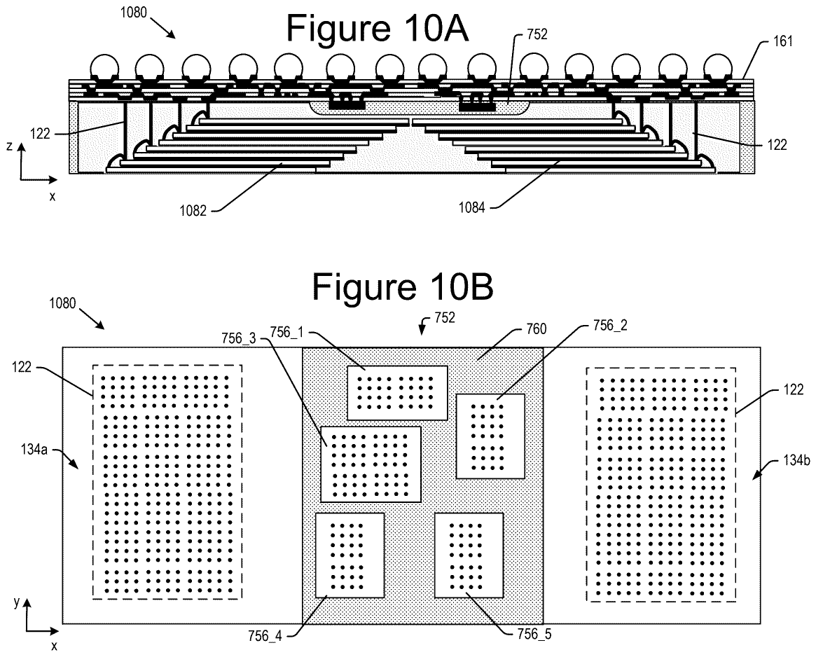

FIGS. 10A-B show another example of an encapsulated die stack 1080 that includes two stacks of dies (e.g., memory dies) 1082 and 1084. In this arrangement, each stack is stepped on only one side. The stepped sides of the stacks with bond wires 122 are arranged so that they are on either side of a central portion of encapsulated die stack 1080 where depression 752 is formed. FIG. 10A shows encapsulated die stack 1080 with RDL 161 while FIG. 10B shows die stack 1080 in top-down view (e.g., along plane where components are bonded) without RDL 161 so that ends of bond wires 122 are visible in active surfaces 134a and 134b on either side of depression 752. FIG. 10B shows five additional dies 756_1 to 756_5 located in depression 752. The number, locations and functions of such additional dies is not limited to any of the examples described. Furthermore, the number and location(s) of die stack(s) in an encapsulated die stack is not limited to the examples described.

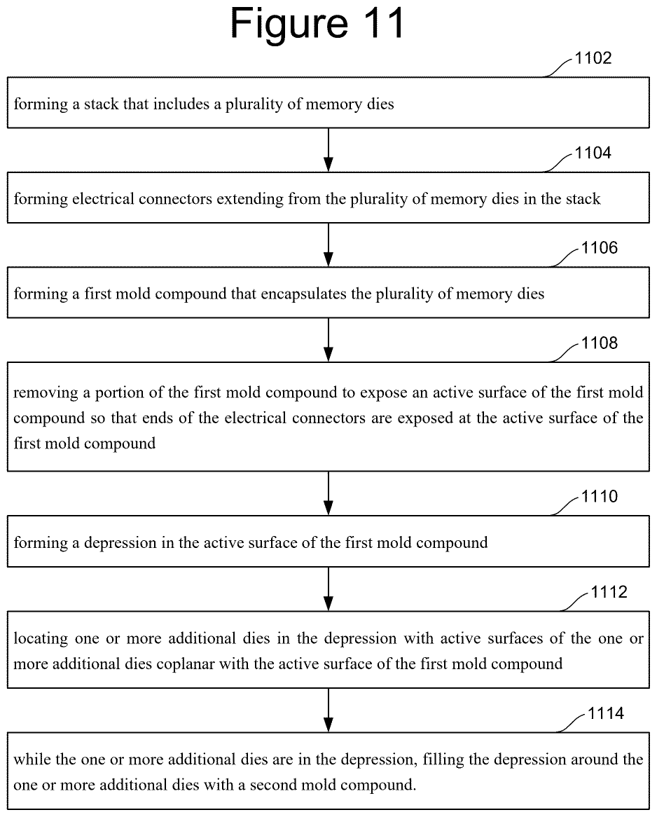

FIG. 11 shows an example of a method that includes forming a stack that includes a plurality of memory dies 1102, forming electrical connectors extending from the plurality of memory dies in the stack 1104 (e.g., bond wires 122), forming a first mold compound that encapsulates the plurality of memory dies 1106 (e.g., first mold compound 134) and removing a portion of the first mold compound to expose an active surface of the first mold compound so that ends of the electrical connectors are exposed at the active surface of the first mold compound 1108 (e.g., removing first mold compound 134 to expose active surface 134a and ends of bond wires 122). The method further includes forming a depression in the active surface of the first mold compound 1110 (e.g., depression 752), locating one or more additional dies in the depression with active surfaces of the one or more additional dies lying coplanar with the active surface of the first mold compound 1112 (e.g., additional dies 756) and while the one or more additional dies are in the depression, filling the depression around the one or more additional dies with a second mold compound 1114 (e.g., filling depression 752 with second mold compound 760).

The present technology may provide several advantages compared with other approaches. For example, by enabling connection of additional dies (e.g., memory controller die) without stud bumps, aspects of the present technology may reduce cost and complexity while improving reliability (e.g., stud bumps may add cost and increase failures). Height (dimensions along z-direction) may be reduced (e.g., by using a thinner die). Area may be reduced (e.g., by placing passive devices in IPD in a depression over a stack instead of placing passive devices beside the stack).

According to an example, an apparatus includes a plurality of memory dies arranged in a stack, electrical connectors configured to transfer signals to and from the plurality of memory dies in the stack and a first mold compound. The plurality of memory dies are encapsulated within the first mold compound so that ends of the electrical connectors extend to an active surface of the first mold compound. The first mold compound has a depression in the active surface and a second mold compound in the depression. A memory controller die is located in the depression. The memory controller die is encapsulated in the second mold compound and has an active surface that is coplanar with the active surface of the first mold compound.

In one or more embodiments, the apparatus includes a redistribution layer (RDL) extending across the active surface of the memory controller and the active surface of the first mold compound.

In one or more embodiments, the RDL has a first surface that extends along and lies in contact with the active surface of the memory controller and the active surface of the first mold compound.

In one or more embodiments, the RDL includes electrical traces that are electrically connected to the ends of the electrical connectors at the active surface of the first mold compound and connected to pads on the active surface of the memory controller die.

In one or more embodiments, the RDL has a second surface that is parallel to the first surface, the second surface has a plurality of solder balls that are electrically connected to the electrical traces.

In one or more embodiments, the apparatus further includes one or more additional dies located in the depression, each of the one or more additional die having bond pads along an active surface that is coplanar with the active surface of the memory controller die.

In one or more embodiments, the one or more additional dies includes an integrated passive device (IPD) die that contains a plurality of capacitors.

In one or more embodiments, the one or more additional die includes a volatile memory die.

In one or more embodiments, the depression is a trench that extends across the active surface of the first mold compound from a first edge to a second edge and the ends of the electrical connectors extend to areas of the active surface of the first mold compound on either side of the trench.

An example of a method includes forming a stack that includes a plurality of memory dies; forming electrical connectors extending from the plurality of memory dies in the stack; forming a first mold compound that encapsulates the plurality of memory dies and removing a portion of the first mold compound to expose an active surface of the first mold compound so that ends of the electrical connectors are exposed at the active surface of the first mold compound. The method further includes forming a depression in the active surface of the first mold compound; locating one or more additional dies in the depression with active surfaces of the one or more additional dies lying coplanar with the active surface of the first mold compound; and while the one or more additional dies are in the depression, filling the depression around the one or more additional dies with a second mold compound.

In one or more embodiments, forming the depression in the active surface of the first mold compound includes forming a trench that extends across the first mold compound by grinding or ablating the first mold compound.

In one or more embodiments, locating the one or more additional dies includes locating one or more of a memory controller die, a volatile memory die and/or an integrated passive device (IPD) die.

In one or more embodiments, the method further includes attaching a redistribution layer (RDL) across the active surface of the first mold compound and the active surface of each of the one or more additional dies.

In one or more embodiments, attaching the RDL includes electrically connecting electrical traces in the RDL to the ends of the electrical connectors at the active surface of the first mold compound and to pads on the active surfaces of the one or more additional dies.

In one or more embodiments, connecting the electrical traces in the RDL to the ends of the electrical connectors and to the pads forms electrical connections from control circuits in the one or more additional dies with components of memory dies including word lines and bit lines of memory arrays formed in the memory dies.

In one or more embodiments, the method further includes forming a plurality of solder balls on a second surface of the RDL that is opposite a first surface of the RDL that lies along and in contact with the active surface of the first mold compound and the active surface of each of the one or more additional dies.

In one or more embodiments, locating the one or more additional dies in the depression with active surfaces of the one or more additional dies lying coplanar with the active surface of the first mold compound includes attaching the active surface of each of the one or more additional dies to a planar surface of a carrier and bringing the planar surface of the carrier and the active surface of the first mold compound together such that the one or more additional dies are located in the depression.

In one or more embodiments, filling the depression around the one or more additional dies with the second mold compound includes causing the second mold compound to flow into the depression while the planar surface of the carrier maintains the active surface of each of the one or more additional dies lying coplanar with the active surface of the first mold compound.

An example of a storage system includes a plurality of memory dies that are stacked along a first direction; electrical connectors electrically connected to the plurality of memory dies, the electrical connectors extending along the first direction through an encapsulant that extends around the plurality of memory dies and ending at an active surface of the encapsulant; a memory controller die connected to the stack of memory dies through the electrical connectors; and means for aligning an active surface of the memory controller die with the active surface of the encapsulant in a coplanar arrangement, maintaining the coplanar arrangement and electrically connecting pads on the active surface of the memory controller die with ends of the electrical connectors at the active surface of the encapsulant.

In one or more embodiments, the active surface of the encapsulant includes a trench and the memory controller die is located in the trench with an integrated passive device (IPD) die and a volatile memory die.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element (other than possibly an adhesive or melted metal used to connect, affix, mount or couple the first and second elements). Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
a plurality of memory dies arranged in a stack;
electrical connectors configured to transfer signals to and from the plurality of memory dies in the stack;
a first mold compound encapsulating the plurality of memory dies such that ends of the electrical connectors extend to an active surface of the first mold compound;
a depression in the active surface of the first mold compound;
a memory controller die located in the depression; and
a second mold compound encapsulating the memory controller die, the second mold compound having an active surface that is coplanar with the active surface of the first mold compound.

2. The apparatus of claim 1, further comprising:
a redistribution layer (RDL) extending across the active surface of the memory controller and the active surface of the first mold compound.

3. The apparatus of claim 2, wherein the RDL has a first surface that extends along and lies in contact with the active surface of the memory controller and the active surface of the first mold compound.

4. The apparatus of claim 3, wherein the RDL includes electrical traces that are electrically connected to the ends of the electrical connectors at the active surface of the first mold compound and connected to pads on the active surface of the memory controller die.

5. The apparatus of claim 4, wherein the RDL has a second surface that is parallel to the first surface, the second surface has a plurality of solder balls that are electrically connected to the electrical traces.

6. The apparatus of claim 1, further comprising:
one or more additional dies located in the depression, each of the one or more additional dies having bond pads along an active surface that is coplanar with the active surface of the memory controller die.

7. The apparatus of claim 6, wherein the one or more additional dies includes an integrated passive device (IPD) die that contains a plurality of capacitors.

8. The apparatus of claim 6, wherein the one or more additional die includes a volatile memory die.

9. The apparatus of claim 1, wherein the depression is a trench that extends across the active surface of the first mold compound from a first edge to a second edge and the ends of the electrical connectors extend to areas of the active surface of the first mold compound on either side of the trench.

10. A method comprising:
forming a stack that includes a plurality of memory dies;
forming electrical connectors extending from the plurality of memory dies in the stack;
forming a first mold compound that encapsulates the plurality of memory dies;
removing a portion of the first mold compound to expose an active surface of the first mold compound so that ends of the electrical connectors are exposed at the active surface of the first mold compound;
forming a depression in the active surface of the first mold compound;
locating one or more additional dies in the depression with active surfaces of the one or more additional dies lying coplanar with the active surface of the first mold compound; and
while the one or more additional dies are in the depression, filling the depression around the one or more additional dies with a second mold compound.

11. The method of claim 10, wherein forming the depression in the active surface of the first mold compound includes forming a trench that extends across the first mold compound by grinding or ablating the first mold compound.

12. The method of claim 10, wherein locating the one or more additional dies includes locating one or more of a memory controller die, a volatile memory die and/or an integrated passive device (IPD) die.

13. The method of claim 10, further comprising:
attaching a redistribution layer (RDL) across the active surface of the first mold compound and the active surface of each of the one or more additional dies.

14. The method of claim 13, wherein attaching the RDL includes electrically connecting electrical traces in the RDL to the ends of the electrical connectors at the active surface of the first mold compound and to pads on the active surfaces of the one or more additional dies.

15. The method of claim 14, wherein connecting the electrical traces in the RDL to the ends of the electrical connectors and to the pads forms electrical connections from control circuits in the one or more additional dies with components of memory dies including word lines and bit lines of memory arrays formed in the memory dies.

16. The method of claim 13, further comprising:
forming a plurality of solder balls on a second surface of the RDL that is opposite a first surface of the RDL that lies along and in contact with the active surface of the first mold compound and the active surface of each of the one or more additional dies.

17. The method of claim 10, wherein locating the one or more additional dies in the depression with active surfaces of the one or more additional dies lying coplanar with the active surface of the first mold compound includes attaching the active surface of each of the one or more additional dies to a planar surface of a carrier and bringing the planar surface of the carrier and the active surface of the first mold compound together such that the one or more additional dies are located in the depression.

18. The method of claim 17, wherein filling the depression around the one or more additional dies with the second mold compound includes causing the second mold compound to flow into the depression while the planar surface of the carrier maintains the active surface of each of the one or more additional dies lying coplanar with the active surface of the first mold compound.

19. A storage system, comprising:
a plurality of memory dies that are stacked along a first direction;
electrical connectors electrically connected to the plurality of memory dies, the electrical connectors extending along the first direction through an encapsulant that extends around the plurality of memory dies and ending at an active surface of the encapsulant;
a memory controller die connected to the stack of memory dies through the electrical connectors; and
means for aligning an active surface of the memory controller die with the active surface of the encapsulant in a coplanar arrangement, maintaining the coplanar arrangement and electrically connecting pads on the active surface of the memory controller die with ends of the electrical connectors at the active surface of the encapsulant.

20. The storage system of claim 19, wherein the active surface of the encapsulant includes a trench and the memory controller die is located in the trench with an integrated passive device (IPD) die and a volatile memory die.
